(19) United States
(12) Patent Application Publication
(10) Pub. No.: US 2013/0314088 A1
(43) Pub. Date: Nov. 28, 2013

(54) MULTI-CHANNEL COIL ARRANGEMENT

(71) Applicant: New York University, (US)

(72) Inventors: Graham Charles Wiggins, New York, NY (US); Ryan Brown, New York, NY (US)

(73) Assignee: New York University, New York, NY (US)

(21) Appl. No.: 13/866,728

(22) Filed: Apr. 19, 2013

Related U.S. Application Data
(60) Provisional application No. 61/635,822, filed on Apr. 19, 2012.

(51) Int. Cl. G01R 33/34

(52) U.S. Cl. CPC G01R 33/34092
USPC 324/322

(57) ABSTRACT

A multi-frequency coil array arrangement can be provided. For example, a plurality of radio frequency coil arrangements can have a first coil arrangement(s) resonant at a single first frequency and a second coil arrangement(s) resonant at a single second frequency which is lower than the first frequency

### CROSS-REFERENCE TO RELATED APPLICATION

This application relates to and claims priority from U.S. Patent Application No. 61/635,822, filed on Apr. 19, 2012, the entire disclosure of which is incorporated herein by reference.

### STATEMENT REGARDING FEDERALLY SPONSORED RESEARCH

Portions of the material described herein were funded, at least in part, by National Institute of Health under grant numbers: R01 AR056260 and R01 AR060238. Therefore, the Federal Government may have certain rights to the invention.

### FIELD OF THE DISCLOSURE

The present disclosure generally relates to a medical imaging apparatus, and in particular to exemplary embodiments of a multi-channel coil array arrangement, which can include a nested sodium and/or proton coil arrangement.

### BACKGROUND INFORMATION

Magnetic Resonance Imaging (“MRI”) can be performed on a number of nuclei such as hydrogen-1 (referred to as proton), helium-3, lithium-7, carbon-13, fluorine-19, oxygen-17, sodium-23, phosphorus-31 and xenon-129. In most MRI applications, hydrogen-1 can be preferred due to its high gyromagnetic ratio and abundance in most tissues in the body, which can translate into high signal-to-noise ratio (“SNR”). However, a subset of applications can use MRI of alternative nuclei in addition to standard proton MRI. For example, quantitative sodium MRI has been shown to be highly specific to the glycosaminoglycan (“GAG”) content in cartilage and could therefore be used as a means of detection and assessment of the degree of biochemical degradation of cartilage in the early stages of osteoarthritis (See, e.g., References 1-7). The above can use a MRI coil array that can be capable of proton and sodium imaging which can add substantial complexity to the coil design. Proton MRI can be used to acquire anatomical reference images and B₀ shimming, while sodium MRI can be used for GAG assessment. A major hurdle for sodium MRI can be its fundamentally low signal due to low sodium content (e.g., approximately 3500 times lower than proton cartilage content) and low gyromagnetic ratio (e.g., approximately 3.78 times lower than the proton gyromagnetic ratio). Therefore, it can be essential to design a sodium receive coil with high sensitivity to the fundamentally low sodium signal.

A structure implemented to enable sodium/proton MRI can include a dual-tuned birdcage coil, where a single birdcage structure can be made resonant at two frequencies by incorporating high-impedance “trap” circuits into the rungs or endrings (See, e.g., References 10-13). An exemplary drawback to this approach can be that energy stored and lost in trap circuits can result in a loss of efficiency. The value of the trap inductor can typically be chosen to sacrifice efficiency of the high frequency channel so as to achieve high efficiency in the low frequency channel (See, e.g., Reference 10). Compared to a mono-nuclear birdcage, an exemplary dual-tuned trap birdcage of the same dimension can provide 80-90% efficiency on the low frequency channel and 40-50% efficiency on the high frequency, for example, proton channel (See, e.g., References 10-11).

Another exemplary drawback to the dual-tuned trap birdcage and other modified dual-tuned birdcages (See, e.g., References 17-19) can be the use of the birdcage for signal detection. A multi-channel receive array for sodium can be expected to substantially boost SNR compared to birdcage coils or single-channel receive coils. The dual-tuned trap birdcage can use numerous identical traps that can make tuning an arduous task, for example, at high fields where trap capacitor value can be small, increasing the effect of stray capacitance and variability with patient loading.

Another exemplary method to facilitate a sodium/proton MRI can include a stripline or Transverse Electro-Magnetic (“TEM”) array where alternating elements or rungs can be tuned to alternating frequencies (See, e.g., References 14-15). However, these designs may not be optimal for low frequency nuclei due to a high degree of shielding by their ground plane, which can result in low coupling to the sample. An alternative design to enable sodium/proton MRI can implement PIN diodes to control the active resonant channel (See, e.g., Reference 16). A drawback to this approach can be that diode losses in the low-frequency channel can reduce its sensitivity.

Thus, it may be beneficial to provide an exemplary multi-channel coil arrangement that can have a high SNR, and which can overcome at least some of the deficiencies described herein above.

### SUMMARY OF EXEMPLARY EMBODIMENTS

To address at least some of these issues, exemplary embodiments of a multi-channel coil array arrangement (e.g., a nested sodium and/or proton coil arrangement) can be provided. For example, hydrogen can be a frequently imaged nucleus because it can be present in biological tissues in great abundance, and because its high gyromagnetic ratio can give a strong signal. However, any nucleus with a net nuclear spin can potentially be imaged with MRI. Such nuclei can include helium-3, lithium-7, carbon-13, fluorine-19, oxygen-17, sodium-23, phosphorus-31 and xenon-129.

According to one exemplary embodiment of the present disclosure, a coil array arrangement can be provided which can include a plurality of coils where subsets of coils can be tuned to a higher frequency or a lower frequency. The coils can have a configuration where the high and low frequencies can correspond to Magnetic Resonance signals from at least two nuclei. The nuclei can include at least one low-frequency nucleus and at least one high frequency nucleus. The low-frequency nuclei can include at least one of: helium-3, lithium-7, carbon-13, fluorine-19, oxygen-17, sodium-23, phosphorus-31 or xenon-129. The high-frequency nuclei typically includes hydrogen, though any of nuclei with higher gyromagnetic ratio than the low-frequency nuclei can be defined as high-frequency nuclei. The coil array can be configured to both transmit and receive radio frequencies at the low-frequency and the high-frequency.

In a further exemplary embodiment of the present disclosure, it can be possible to place the high and low frequency coils at substantially the same distance from the object to be imaged.

According to a still further exemplary embodiment of the present disclosure, it can be possible to provide excitation for the lower frequency nucleus with a separate structure at a greater distance from the object, such as an encircling birdcage volume coil.

In yet another exemplary embodiment of the present disclosure, the encircling birdcage volume coil can be of a high pass design to avoid interaction with the higher frequency coil elements.

According to yet a further exemplary embodiment, the exemplary array can be sensitive to MR signals from two nuclei, referred to as the low-frequency nuclei, for example sodium, phosphorous, or carbon, and high-frequency nuclei, typically hydrogen. The exemplary array can be capable of both RF transmission and reception at both frequencies. The exemplary array can be comprised of a multitude of high-frequency and low-frequency receive coils to improve sensitivity over a volume coil. The exemplary receive coils can contain no in-line diodes, inductors, or other resistive circuitry that degrades sensitivity. Exemplary high-frequency transmit and receive capabilities can be provided by one or more coils placed on the same former as the low-frequency receive coils, for example, to avoid RF shielding of the high-frequency coils by the low-frequency coils. In this way, certain exemplary embodiments can include low-frequency receive performance that may not be degraded by high-frequency capability. Further, the exemplary low-frequency receive capability can be provided by a multitude of receive coils placed on a fixed or flexible former that closely fits the targeted anatomy. The exemplary low-frequency transmit capability can be provided dually by the low-frequency receive coils, or preferably by a standalone transmit coil that encircles or surrounds the low-frequency receive coils.

In the exemplary case of a surrounding array, low-frequency transmit capability can be provided by an encircling birdcage coil. A high-pass birdcage can be preferred in which the uniform imaging mode can have the third-greatest frequency and less useful imaging modes can occur at lower frequencies, so as to avoid interaction with the high-frequency nuclei. In the exemplary case of separate low-frequency transmit and receive coils, low-frequency receive (e.g., transmit) coils can be detuned during low-frequency transmit (e.g., receive) using standard methods.

These and other objects of the present disclosure can be achieved by provision of a multi-frequency coil array arrangement that can include a plurality of radio frequency coil arrangements having a first coil arrangement(s) resonant at a single first frequency and a second coil arrangement(s) resonant at a single second frequency which is lower than the first frequency. Each of the RF coils can include a receive element(s) which can be located at or near a target object. The receive element(s) for first RF coil arrangement(s) can be located at substantially a same distance from the target object as the receive element(s) for the second RF coil arrangement(s), and the receive element(s) for the first RF coil arrangement(s) can be located at least one of within or interspersed with the receive element(s) for the second RF coil arrangement(s) so as to substantially avoid shielding by the receive element(s) of the second RF coil arrangement(s).

In some exemplary embodiments of the present disclosure, there can be an excitation structure(s) resonant only at the second frequency configured to receive a signal generated by the RF coil arrangements. The excitation structure(s) can be an encircling volume coil structure, and the encircling volume coil structure can be (i) a birdcage (i) a Transverse Electro-Magnetic array (TEM) or (iii) an array of excitation coils. The excitation structure(s) can be a high pass birdcage configured to avoid an interaction of higher modes of the high pass birdcage associated with the receive element(s) for the first RF coil arrangement(s).

In certain exemplary embodiments of the present disclosure, there can be computing arrangement configured to receive a signal from the excitation structure based on the second frequency, and generate a uniform reference image based on the signal. In some exemplary embodiments of the present disclosure, the receive element(s) for the second RF coil arrangement(s) can be a transmit-receive element, which can be configured to function, at least in part, as a lower frequency transmit structure. A third coil arrangement(s) can be resonant at a third frequency which is different than the first and second frequencies. The first frequency and the second frequency can be based on a magnetic resonance signal(s) of two nuclei of the target object. One of the two nuclei can be a low-frequency nucleus comprising helium-3, lithium-7, carbon-13, fluorine-19, oxygen-17, sodium-23, phosphorus-31 or xenon-129.

In a further exemplary embodiment of the present disclosure is a dual frequency coil array arrangement that can have a plurality of coil arrangements, each coil arrangement having a coil element that can be resonant at a non-dual tuned frequency. The coil elements can include receive elements, and the receive elements that have a lower frequency can be located substantially near an object to be imaged. The receive elements having higher frequencies can be located at substantially a same distance from the object as the receive elements having lower frequency, and the receive elements for the higher frequency coil arrangements can be placed within or interspersed with the receive elements for the lower frequency coil arrangements to avoid shielding by the receive elements of the lower frequency receive arrangements.

In certain exemplary embodiments of the present disclosure, excitation for the lower frequency coil arrangements can be provided by an excitation arrangement resonant only at lower frequencies. The excitation arrangement can be an encircling volume coil structure, that can be (i) a birdcage (i) a TEM or (iii) an array of excitation coils. The excitation arrangement can also be a high pass birdcage configured to avoid interaction of higher modes of the high pass birdcage with the higher frequency coil arrangements. The lower frequency coil arrangements can be configured to generate a signal while the receive elements of lower frequency coil arrangements can be detuned in order to generate a uniform reference image.

These and other objects, features and advantages of the present disclosure will become apparent upon reading the following detailed description of exemplary embodiments of the present disclosure, when taken in conjunction with the accompanying exemplary drawings and appended claims.

### BRIEF DESCRIPTION OF THE DRAWINGS

Further objects, features and advantages of the present disclosure will become apparent from the following detailed description taken in conjunction with the accompanying Figures showing illustrative embodiments of the present disclosure, in which:

FIGS. 1A-1C are a set of exemplary partial electrical schematic diagrams of the exemplary dual-nuclei array according to an exemplary embodiment of the present disclosure;

FIG. 2 is an exemplary graph of an exemplary spectra of a tuned sodium birdcage along with a proton coil according to an exemplary embodiment of the present disclosure;

FIG. 3 is a set of exemplary images of sodium phantom SNR maps according to an exemplary embodiment of the present disclosure;

FIGS. 4A and 4B are exemplary SNR profile graphs according to an exemplary embodiment of the present disclosure;

FIG. 5 is a set of exemplary images of in-vivo sodium SNR maps according to an exemplary embodiment of the present disclosure;

FIG. 6 is a set of exemplary images of in-vivo sodium 3D radial co-registered images according to an exemplary embodiment of the present disclosure;

FIG. 7 is a set of further exemplary in-vivo proton SNR maps according to an exemplary embodiment of the present disclosure;

FIGS. 8A and 8B are exemplary graphs of in-vivo SNR profiles through sagittal SNR maps according to an exemplary embodiment of the present disclosure; and

FIG. 9 is an illustration of an exemplary block diagram of an exemplary system in accordance with certain exemplary embodiments of the present disclosure.

Throughout the drawings, the same reference numerals and characters, unless otherwise stated, are used to denote like features, elements, components, or portions of the illustrated embodiments. Moreover, while the present disclosure will now be described in detail with reference to the figures, it is done so in connection with the illustrative embodiments and is not limited by the particular embodiments illustrated in the figures.

### DETAILED DESCRIPTION OF EXEMPLARY EMBODIMENTS

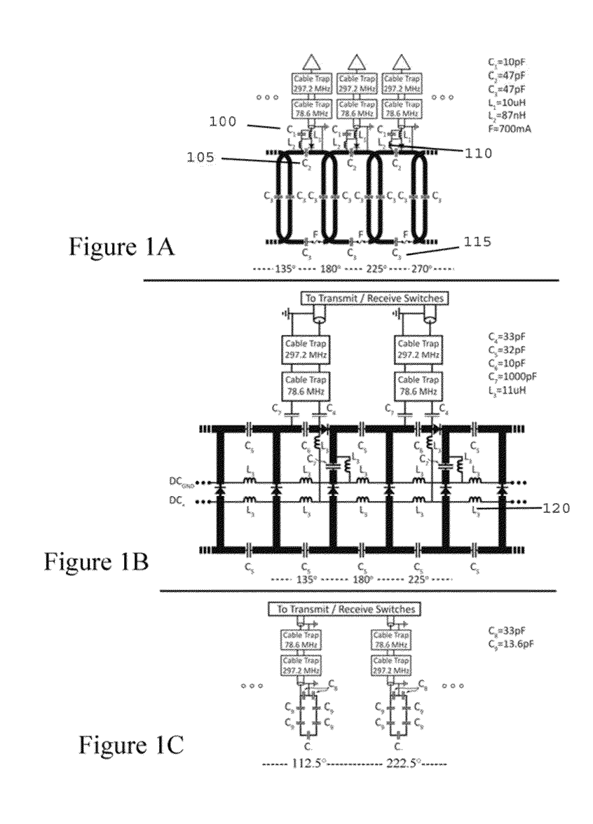

According to certain exemplary embodiments of the present disclosure, a multi-channel (e.g., 8-channel) sodium array and/or coil can be provided. The exemplary coil can provide a high SNR on the low frequency channel, for example, for sodium in a human knee articular cartilage. An exemplary array of, for example, eight receive-only rectangular coils, can be provided on, for example, an 0.8 mm thick FR4 copper-clad (e.g., 1 oz/ft²) circuit board with, for example, 0.8 cm conductor width and arranged on a close-fitting acrylic former with, for example, a 20.3 cm diameter. An exemplary arc length of the exemplary coils can be 8.8 cm (500), such that the coils can be symmetrically arranged and partially overlapped (See e.g., Reference 21) in the azimuthal direction to reduce inductive coupling (e.g., as illustrated in FIG. 1A). The exemplary coils can be, for example, about 15 cm in length (e.g., along the direction of the main magnetic field) to cover knee cartilage over an exemplary range of about 10 to 12 cm.

Each exemplary coil can be tuned to the sodium resonance frequency at about 7T (e.g., about 78.6 MHz) using four distributed capacitors (e.g., three fixed capacitors such as series 11, Voltronics Corp., Denville, N.J., and one variable capacitor), and matched to 50) while loaded with a cylindrical phantom with 11.5 cm diameter (e.g., 1890 mL water doped with 7.18 g NiSO₄.6H₂O and 9.5 g NaCl). A two-stage matching network (e.g., C1 (100), C2 (105), and L2 (110) in FIG. 1A) (See e.g., Reference 22) can be implemented to reduce the value of the detuning capacitor compared to a single-stage match, thereby increasing the value of the corresponding inductor and the quality factor (Q) of the detuning circuit. A PIN diode (e.g., MA4P4002B, M/A-COM Technology Solutions Inc., Lowell, Ma) controlled tank circuit can be used to actively detune the coils during sodium transmit, and proton transmit and receive. The output of each coil can be connected to a low-impedance preamplifier (e.g., Stark Contrast, Erlangen, Germany) using coaxial cable of appropriate length for preamplifier decoupling (See e.g., Reference 21). An exemplary benefit of the two-stage match can be evidenced by improved detuning and preamplifier decoupling, as compared to a single-stage match.

The exemplary two-stage match can symmetrically distribute capacitance such that C2 (105) and C3 (115) can be at least approximately equal (See, e.g., FIG. 1A), which can improve current distribution uniformity around the exemplary coil. For example, a fuse rated to, for example, 700 mA, can be added to each coil to provide supplementary protection in the event of an active detuning failure. To reduce common mode currents on the coaxial cables, shielded cable traps tuned to the sodium and proton frequencies can be inserted at the output of each coil. Cable traps at both frequencies can be used on all cables as common mode currents, and can be induced into neighboring coaxial cables regardless of a given coil's resonance.

The Q can be measured on a network analyzer (e.g., ENA series, Agilent Technologies, Santa Clara, Calif.) using a shielded double probe coupled lightly to a coil while it can be unloaded and loaded with the cylindrical phantom. Q measurements can be made in, for example, four environments: a) in isolation, b) in the presence of the eight-channel array and interface electronics, c) in the presence of the aforementioned and the transmit sodium birdcage (e.g., as described in the following section), and d) in the presence of the aforementioned and the proton array. For exemplary environments (b)-(d), neighboring sodium coils and the sodium birdcage can be actively detuned. Coil noise as a percentage of total noise can be calculated according to 1−√[1−(Q_{loaded}/Q_{unloaded})], where coil noise can include conductor and radiative losses and the total noise accounts for coil and sample losses (See, e.g., Reference 23). Active detuning of an unloaded coil can be measured as the change in the transmission coefficient (S₂₁) of, for example, the double shielded probe coupled lightly to the coil when the diode controlled tank circuit was forward and reverse biased. Preamplifier decoupling of an unloaded coil can be similarly characterized as the change in S₂₁ when the preamplifier can be powered and the coil detuning diode can be reverse biased versus when the preamplifier can be removed from its socket.

FIGS. 1A-1C illustrate a set of exemplary partial electrical schematic diagrams of the dual-nuclei array. In particular FIG. 1A illustrates a partial schematic diagram of an exemplary eight-channel sodium receive array. FIG. 1B illustrates a partial schematic diagram of an exemplary detunable transmit-receive sodium birdcage. FIG. 1C illustrates a partial schematic diagram of an exemplary transmit-receive proton array. An exemplary azimuthal angle can be indicated at the bottom of each panel, where 0° can be the anterior direction and 180° can be the posterior direction. Capacitor and inductor values can be, for example, +/−10%.

Exemplary Detunable Sodium Birdcage Coil

An exemplary detunable birdcage can be provided to provide excitation at the sodium frequency. Its dimensions can be based on exemplary trade-offs between high B₁⁺ uniformity, which can use a larger length to diameter ratio, and high peak B₁⁺ that can call for small diameter and smaller length to diameter ratio. According to another exemplary embodiment of the present disclosure, the exemplary birdcage can fit coaxially around the sodium receive array former with minimal disturbance to the contralateral leg. Full-wave simulations using a current mode expansion with Dyadic Green's functions (“DGF”) (See e.g., Reference 24) can be utilized to guide the choice of exemplary birdcage dimensions by calculating the B₁⁺ field every 0.25 cm along a 28 cm line on main axis of candidate birdcages with a range of lengths and diameters.

The exemplary determinations can assume a uniform cylindrical sample with 13 cm diameter and dielectric properties of muscle at 78.6 MHz (e.g., relative permittivity=69 and conductivity=0.69 S/m) (See, e.g., Reference 25). Exemplary metrics for comparison can include: a) peak B₁⁺, b) ratio of B₁⁺ at x=0, y=0, z=6 cm to peak B₁⁺, for example, where the birdcage can be centered at the origin, the main axis of the birdcage and the static magnetic field can be oriented along z, and +/−6 cm can be chosen as an exemplary knee articular cartilage imaging range, and c) the full width at half maximum (FWHM) B₁⁺, for example, defined as the range over which B₁⁺ can be greater than one-half of the peak B₁⁺. Exemplary DGF calculations can indicate that a birdcage with 25.4 cm diameter and about 20 cm length can provide sufficient peak B₁⁺ and uniformity over the targeted cartilage region, while also convenient to construct given the anatomical and mechanical restrictions (e.g., as shown in Table 1 below).

TABLE 1
Q measurements for elements of the developed dual-nuclei array.

| Coil | Environment | Q_{unloaded} | Q_{loaded} | Coil Noise (%) |
|---|---|---|---|---|
| Sodium receive coil | 1 | 330 | 105 | 17 |
| Sodium receive coil | 2 | 260 | 85 | 18 |
| Sodium receive coil | 3 | 190 | 70 | 21 |
| Sodium receive coil | 4 | 180 | 70 | 22 |
| Sodium birdcage | 4 | 110 | 55 | 29 |
| Proton coil | 4 | 205 | 155 | 51 |

An exemplary high-pass birdcage design can be selected because, for example, its high-order modes can occur below 78.6 MHz, and it may not interact with the proton channel at 297.2 MHz. The exemplary eight rung birdcage can be positioned such that its rungs (e.g., a 1.3 cm conductor width) can be positioned above the centers of the sodium receive coils, as positioning the rungs above the overlap regions of the array can have a detrimental effect on the inductive decoupling of the array elements (e.g., as shown in the partial schematic diagram of FIG. 1B). The exemplary uniform imaging mode of the birdcage can be tuned to 78.6 MHz and two quadrature drivepoints can be matched to 50Ω through series capacitors (e.g., 25 series, Voltronics Corp., Denville, N.J.).

To activate, and/or deactivate, the exemplary birdcage during sodium transmit (e.g., sodium array receive or proton transmit/receive), PIN diodes can be inserted in series with each rung and in the endrings at the drivepoints. To reduce the effective size of the Direct Current (“DC”) loop used to power the diodes, a ring of radio-frequency (“RF”) chokes (e.g., see L3 (120) in FIG. 1B) can be formed around the birdcage center. The value of the RF choke (e.g., about 11 nH) can be selected to suppress current at both about 78.6 MHz and about 297.2 MHz. The detuning diodes (e.g., numbering 10) can be fed by combining four DC bias lines from the scanner that each supplied 100 mA during forward bias and −30V during reverse bias. Exemplary resistors can be inserted as needed in the DC path such that the bias current through each diode can be approximately equal (for simplicity, exemplary resistors are not shown in FIG. 1B). To evaluate diode detuning, S₂₁ can be measured through a small shielded double loop probe lightly coupled to the unloaded birdcage when the diodes can be forward biased and reverse biased. For this measurement, coaxial cables can be disconnected from the drivepoints.

The birdcage can be driven in quadrature through a lumped element quadrature hybrid whose isolated port can be terminated with a 50Ω load. The sodium birdcage can also be utilized for reception when the sodium array coils can be detuned. For example, each birdcage port can be connected to a preamplifier via a transmit-receive switch.

Exemplary Four Channel Proton Transmit/Receive Array

The exemplary proton array can provide adequate SNR of the knee articular cartilage for anatomical reference and B₀ shimming with minimal disturbance to the sodium channel. This can be accomplished, for example, with an array of four proton coils. To reduce shielding of the proton coils by the sodium receive array and sodium birdcage, the proton coils can be placed on the inner former (e.g., about 20.3 cm diameter) rather than the outer former (e.g. about 25.4 cm diameter). The exemplary proton coils can be 3 cm (e.g., arc length)×7 cm (e.g., head-foot length) and positioned concentric to four sodium receive coils with azimuthal positions of 0°, 90°, 180°, and 270°, where 0° represents the anterior direction and 180° the posterior direction (e.g., as illustrated in a partial schematic diagram of FIG. 1C).

A relatively narrow conductor width of about 0.2 cm can be selected to reduce shielding and eddy current loading of the sodium receive coils and sodium birdcage. Their geometry can be chosen empirically given tradeoffs between high B₁⁺ uniformity and coverage provided by large coils and low coupling between neighboring coils afforded by small coils. Seven capacitors (e.g., 25 series, Voltronics Corp., Denville, N.J.) can be distributed along each proton coil to insure that current can be well-distributed. RF can be transmitted to each proton coil through, for example, a two-stage cascade of three Wilkinson power splitters that can divide the transmit power into four equal parts. To generate a birdcage-like excitation, a phase shift possibly equal to each coil's azimuthal position can be provided, or built-in, using appropriate lengths of coaxial cable. For RF receive, each coil can be connected to a preamplifier via a PIN diode controlled transmit/receive switch with the appropriate length of coaxial cable for preamplifier decoupling. Preamplifier decoupling can be measured as described above. Detuning circuits may not be needed for certain exemplary transmit/receive arrays.

Exemplary Sodium Imaging

Exemplary imaging can be performed on, for example, a whole-body 7 T scanner (e.g., MAGNETOM, Siemens Medical Solutions, Erlangen, Germany). The exemplary dual-nuclei array can be compared to a commercially available four rung mono-nuclear transmit-receive sodium birdcage coil, for example, with 20 cm diameter and 17 cm length (e.g., Rapid Biomedical, Germany). Coil performance can be initially evaluated on the water phantom. The transmit voltage that can be used to generate, for example, a 90° flip angle can be determined by fitting the signal intensity of gradient echo images in the central transverse slice over a range of transmit voltages to a sine curve (e.g., 500 μs RF pulse, TE=3.5 ms, TR=100 ms, voxel size=4.7 mm×4.7 mm×25 mm, acquisition matrix=64×64, receiver bandwidth=260 Hz/pixel, signal averages=1, and acquisition time=8 s).

Receive signal for SNR analysis can be acquired in gradient echo images in the central transverse, sagittal, and coronal planes with the transmit voltage used for a 90° flip angle and the above imaging parameters. An exemplary analogous noise image can be acquired without RF excitation to allow calculation of the optimum SNR at each voxel (See, e.g., Reference 26). These exemplary measurements can be repeated with both coils on, for example, the right knee of a subject. Because in-vivo SNR can be much lower than phantom SNR, mean in-vivo SNR maps in the transverse, coronal, and sagittal planes can be generated by averaging 16 SNR maps with, for example, the above imaging parameters. The utility of the exemplary coil can be further demonstrated through in-vivo images acquired with a 3D radial pulse sequence with the following exemplary parameters: 8000 projections, TE=0.4 ms, TR=100 ms, flip angle=90° with a pulse duration of 500 his, field of view=20 cm, voxel size=2 mm isotropic, and acquisition time=13:25 min.

Exemplary Proton Imaging

The exemplary proton side of the dual-nuclei array can be compared to a commercially available 16 rung mono-nuclear transmit-receive proton birdcage extremity coil (e.g., a four port drive, two channel receive, 21 cm diameter, and 14 cm length, from Invivo Corp, Gainesville, Fl.). Images of, for example, the right knee can be acquired with both coils. The transmit voltage used for a 90° flip angle in the center of the knee in this exemplary embodiment, can be determined using a turbo fast low-angle shot (“FLASH”) pulse sequence with a series of saturation-no-recovery images acquired over a range of preconditioning pulse amplitudes (See, e.g., References 27).

After transmit voltage calibration, exemplary signal maps can be acquired with a gradient echo pulse sequence with the following exemplary imaging parameters: TE=4.07 ms, TR=200 ms, voxel size=0.86×0.86×3 mm³, acquisition matrix=256×256, flip angle=20°, receiver bandwidth=300 Hz/pixel, signal averages=1, and acquisition time=51 s. Noise data can be acquired with no RF excitation to facilitate the exemplary calculation of optimum SNR at each voxel. B₀ shimming with the exemplary developed proton coil can be critical for sodium imaging for which T2 can typically be very short. Three plane B₀ maps can be acquired with the exemplary system shim values and after the vendor-provided shim algorithm can be iterated five times on a cubic volume with, for example, 12 cm length centered on the patella. To calculate B₀, complex data from gradient echo images (e.g., TR=30 ms, voxel size=1×1×6 mm³, receiver bandwidth=1000 Hz/pixel, and two signal averages) with multiple echo times (e.g., TE=2.0, 2.2, 2.4, and 2.6 ms) can be processed using an exemplary three-point Dixon method (See, e.g., Reference 28).

### Exemplary Results of Exemplary Embodiments

Exemplary Sodium

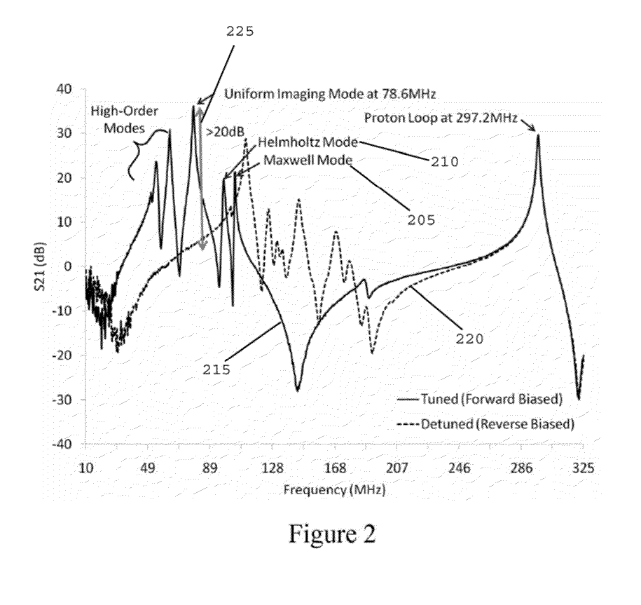

The exemplary birdcage spectra shown in FIG. 2, can provide the high-order imaging modes, which can occur below the uniform imaging mode at about 78.6 MHz (e.g., the Maxwell 205 and Helmholtz 210 endring modes can also be evident). Diode detuning on the exemplary dual-nuclei sodium birdcage can provide approximately 20 dB of sensitivity isolation at 78.6 MHz. For example, the resonances of the exemplary detuned birdcage can be shifted higher in frequency but may not approach the proton resonance at approximately 297.2 MHz. In this exemplary embodiment, interaction with the proton channel can be avoided when the exemplary birdcage can be tuned and detuned.

The exemplary transmit voltage that can be used for 90° excitation with a 1 ms hard pulse in the center of the phantom and in-vivo can be 215 V for the exemplary dual-nuclei sodium birdcage and 167 V (e.g., phantom) and 107 V (e.g., in-vivo) for the exemplary mono-nuclear sodium birdcage. FIG. 2 illustrates exemplary spectra of the tuned (e.g., forward biased PIN diodes 215) and detuned (e.g., reverse biased PIN diodes 220) sodium birdcage along with an exemplary proton coil. Diode detuning can provide greater than 20 dB of isolation at 78.6 MHz (e.g., 225). The exemplary proton coil can show insignificant interaction with the tuned and detuned sodium birdcage at the proton resonance frequency at about 297.2 MHz.

Exemplary sodium coil Q measurements (see, e.g., Table 2 below) can show that the percentage of coil noise associated with a single coil in isolation can be similar to that of the coil in position with the complete sodium receive array, detunable sodium birdcage, proton array, and associated electronics. S₂₁ measurements can indicate that sodium receive coil sensitivity can be reduced by more than 40 dB by active diode detuning. Active detuning can result in split resonances at 60.5 MHz and 105 MHz, which can be well out of range of exemplary frequencies of interest, for example, about 78.6 MHz and 297.2 MHz. Neighboring coils can be coupled by less than −14 dB and next-nearest neighbors can be coupled by less than −8 dB when loaded by the phantom. Preamplifier decoupling can provide more than 25 dB of isolation.

TABLE 2
DGF calculations of B₁⁺ characteristics for sodium birdcages with a range of
diameters and lengths.

| | Diameter (cm) | | | | | | | | |
|---|---|---|---|---|---|---|---|---|---|
| | 22.9 | | | 25.4 | | | 27.9 | | |
| | Peak | FWHM | B₁⁺ | Peak | FWHM | B₁⁺ | Peak | FWHM | B₁⁺ |
| Length (cm) | B₁⁺ | (cm) | ratio | B₁⁺ | (cm) | ratio | B₁⁺ | (cm) | ratio |
| 16 | 1.00 | 16.5 | 0.70 | 0.97 | 17.5 | 0.72 | 0.94 | 19.0 | 0.75 |
| 18 | 0.95 | 18.5 | 0.76 | 0.93 | 19.5 | 0.77 | 0.91 | 20.5 | 0.79 |
| 20 | 0.90 | 20.5 | 0.82 | 0.89 | 21.0 | 0.82 | 0.88 | 22.0 | 0.83 |
| 22 | 0.85 | 22.5 | 0.88 | 0.85 | 23.0 | 0.87 | 0.84 | 24.0 | 0.86 |
| 24 | 0.81 | 24.5 | 0.93 | 0.81 | 25.0 | 0.91 | 0.81 | 25.5 | 0.90 |

In Table 2, the exemplary values in each cell can include: peak B₁⁺ normalized to the peak value for the birdcage with 22.9 cm diameter and 16 cm length, B₁⁺ FWHM (cm), and the ratio of B₁⁺ at x=0, y=0, z=6 cm to B₁⁺ at the origin. Values for the dimensions of the constructed coil are shown in bold type.

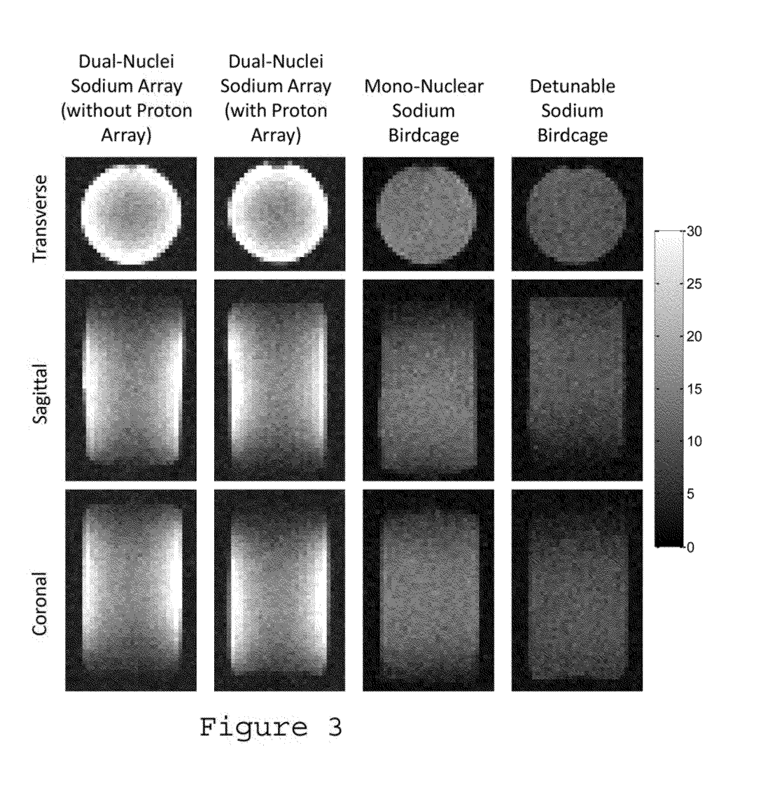

Exemplary SNR maps, for example, as illustrated in FIG. 3, can indicate that the developed dual-nuclei sodium array can provide approximately 10% SNR gain in the center of the phantom over the commercial mono-nuclear sodium birdcage 415 and approximately 2.3-fold gain in the phantom periphery using optimal SNR reconstruction. Conventional sum-of-squares SNR reconstruction can result in similar gain at the center and approximately 1.8-fold gain in the phantom periphery. Notably, the exemplary proton array can have a negligible effect on sodium SNR. The SNR of the nine central voxels in transverse images can be about 11.3±1.0 (e.g., mean±standard deviation) for the exemplary dual-nuclei sodium array before the proton array 405 can be added, 11.5±0.6 for the dual-nuclei sodium array in the presence of the proton array 410, about 10.2±1.0 for the mono-nuclear sodium birdcage 415, and about 7.6±0.7 for the detunable sodium birdcage 420.

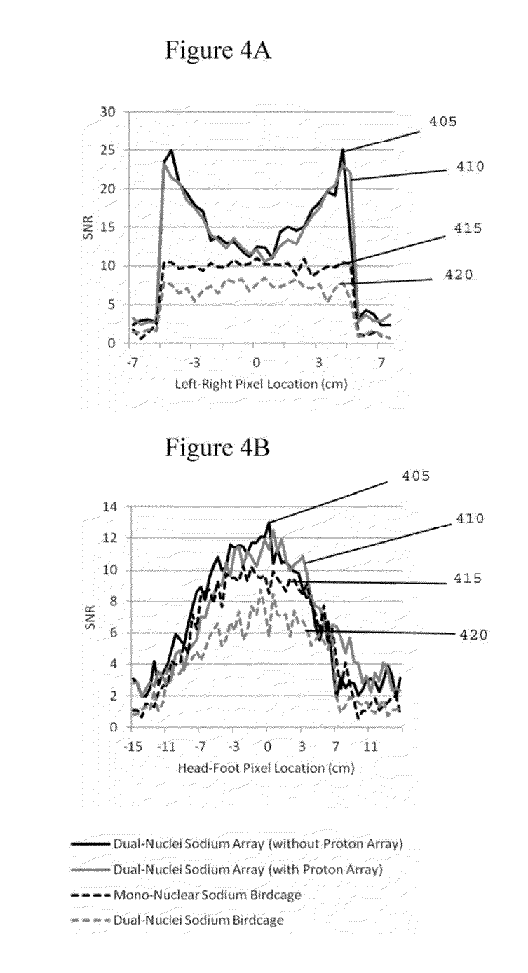

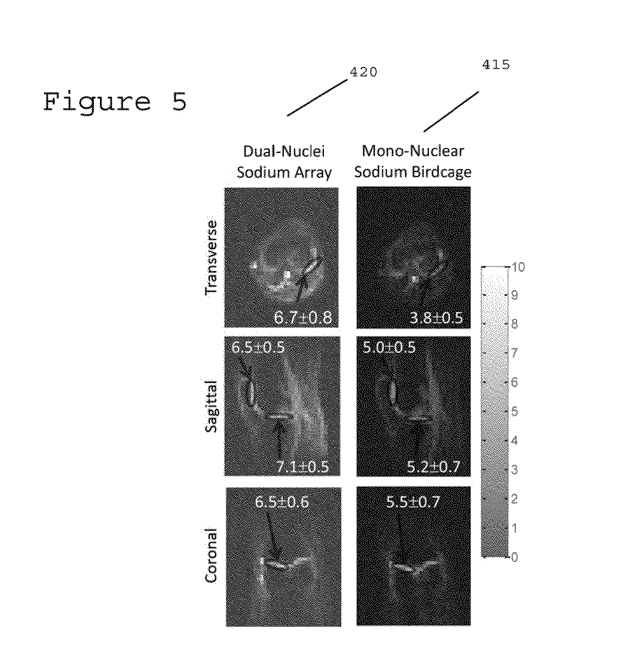

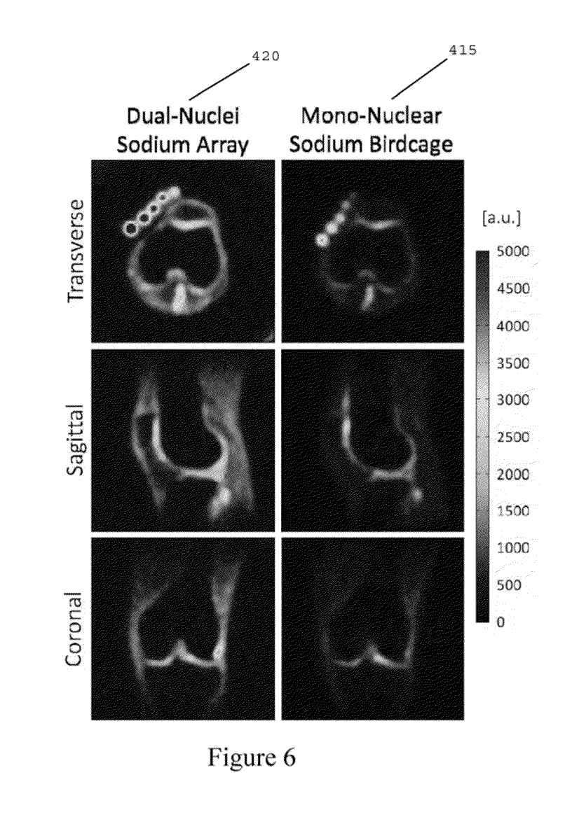

Additionally, the mono-nuclear birdcage SNR can be, for example, about 34% greater than the detunable sodium birdcage due to the increased diameter of the latter coil, and detuning diodes that can be used to accommodate the receive array. Although the exemplary eight-channel array can be the primary means for reception, receive capability can also be available on the exemplary detunable sodium birdcage 420 to provide a uniform image useful for sodium quantification. Exemplary SNR profiles through the transverse and sagittal SNR maps can also indicate the improved performance of the sodium array, particularly in the phantom periphery (e.g., FIG. 4A). The exemplary SNR profiles in the head-foot direction (e.g., FIG. 4B) can indicate that the sodium array 405 and 410 and mono-nuclear sodium birdcage 415 can provide similar coverage. In-vivo sodium exemplary SNR maps can similarly show that the exemplary developed array can provide gains of, for example, 1.2 to 1.7-fold in the articular cartilage over the mono-nuclear birdcage 415 (e.g., see FIG. 5). A comparison of 3D radial acquisitions using the dual-nuclei 415 and mono-nuclear 420 coils on the same subject are shown in FIG. 6. Although it can be complex to determine the exemplary SNR of a radial acquisition, the sensitivity of the exemplary developed dual-nuclei coil 420 can be clearly superior to that of the mono-nuclear volume coil 415, for example, in the patellar and femoro-tibial cartilage.

Exemplary Proton

Neighboring proton coils can be coupled by, for example, −9.4 to −11.9 dB, and next nearest neighbors can be coupled by −11.8 to −13.0 dB, while the array can be loaded with the phantom. Preamplifier decoupling can provide greater than about 14 dB isolation. The transmit voltage used for 90° excitation in the center of the knee with a 1 ms hard pulse for the dual-nuclei array and mono-nuclear birdcage can be about 270 V and 190 V, respectively.

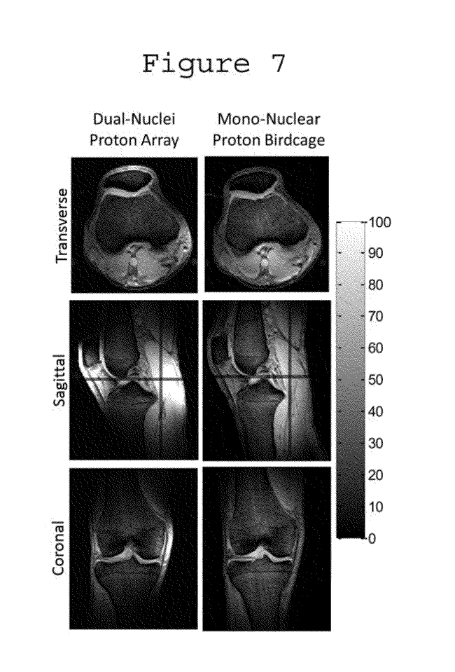

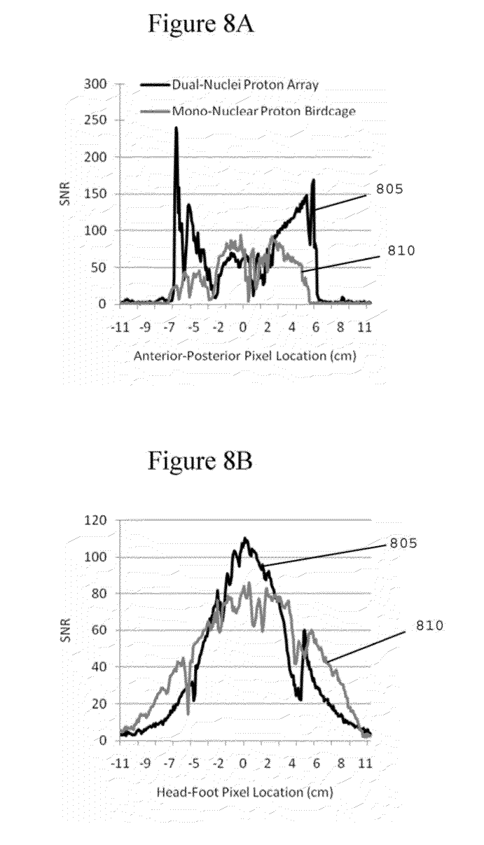

In-vivo exemplary proton SNR maps (e.g., see FIG. 7) and profiles (e.g., see exemplary graphs of FIGS. 8A and 8B) show that the dual-nuclei proton coil 805 can achieve lower SNR in the center compared to the mono-nuclear proton birdcage 810, but higher SNR in the periphery. The coverage of the exemplary coil in the head-foot direction can be less than that of mono-nuclear birdcage 810 but can be adequate for the purposes of B₀ shimming and obtaining anatomical reference images. The FWHM coverage can be approximately 8.9 cm and 11.9 cm for the dual-nuclei proton array 805 and mono-nuclear birdcage 810, respectively. The off-resonance of all voxels in the three-plane B₀ maps inside the shim volume (e.g., voxels outside the shim volume or in the background air can be removed) can be 64.0±131.7 Hz with the exemplary shim settings and 32.6±82.2 Hz after performing B₀ shimming.

### Discussion of Additional Exemplary Embodiments

Exemplary embodiments of the dual-nuclei multiple-channel array can provide substantial sodium channel SNR gains over a conventional mono-nuclear sodium birdcage. By judiciously managing the resonances of each component of the array, the sodium receive channels can be maintained in the most favorable form, without SNR-lowering circuitry that can be commonly used in dual-tuned coils such as trap circuits or in-line PIN diodes. The exemplary approach can result in sodium SNR gains of approximately 1.2 to 1.7 in-vivo, and can additionally provide proton B₀ shimming and co-registered anatomical reference imaging capabilities. Exemplary Q measurements can indicate that the exemplary sodium receive coils can be substantially unaffected by the detuned sodium birdcage or proton coils. The exemplary proton coils may not be conducive to coupling at the sodium frequency due to their relatively high-impedance (e.g., the total series capacitance and inductance of the proton coils can be approximately 2.3 pF and 123 nH, respectively, which can translate into a series impedance of −j808.3Ω at 78.6 MHz) and short perimeter (e.g., 20 cm or 19 times shorter than one wavelength at 78.6 MHz.

Traditional dual frequency MR coils have been created by making a single structure resonant at two frequencies through the incorporation of resonant trap circuits. These circuits can be lossy and exact a sensitivity penalty at both frequencies. It can be possible to make two separate resonant structures nested inside each other, such as two nested birdcages, but it may not possible to put the low frequency birdcage inside the high frequency birdcage because the low frequency structure can act as a shield for the higher frequency. Putting the high frequency structure inside the low frequency coil can also be possible, but this would force the diameter of the low frequency coil to be larger, which also exacts a penalty for sensitivity compared to a smaller coil. The lower frequency coil can traditionally detect a signal from nuclei such as 23Na or 31P, which intrinsically can be much lower signals as compared to the normal 1H (e.g., proton) signal, and therefore, certain exemplary embodiments can maximize sensitivity at the lower frequency.

Exemplary embodiments of the present disclosure can place a very sensitive receive array for the lower frequency on the innermost level of the coil, as close as possible to the target object (e.g., a biological structure, such as a human/animal body). For example, an exemplary minimum distance can be about 5 mm from the target object, and an exemplary maximum distance can be about 70 cm, and the receive array can be placed at an distance within the exemplary range above. It should be noted that in some exemplary embodiments of the present disclosure, a smaller minimum distance and a larger maximum distance can be used

Exemplary embodiments can also use traditional single tuned receive loops, which may not be compromised by any dual tuning electronics. The problem of screening by the low frequency structures can be mitigated by placing small transmit receive elements tuned to the higher frequency on the same former as the close fitting low frequency receive array, placed inside various of the low frequency receive loops. This can facilitate the acquisition of standard proton images of good quality which can be, for example, sufficient for B₀ shimming and anatomical localization. Transmit excitation for the lower frequency can be provided by a larger diameter birdcage coil, which can encircle the whole structure. By choosing a high pass birdcage, as opposed to a low pass structure, certain exemplary embodiments can ensure that none of the multiple resonances of the birdcage can come close to the higher frequency, which can avoid interaction between the low frequency and high frequency coil structures.

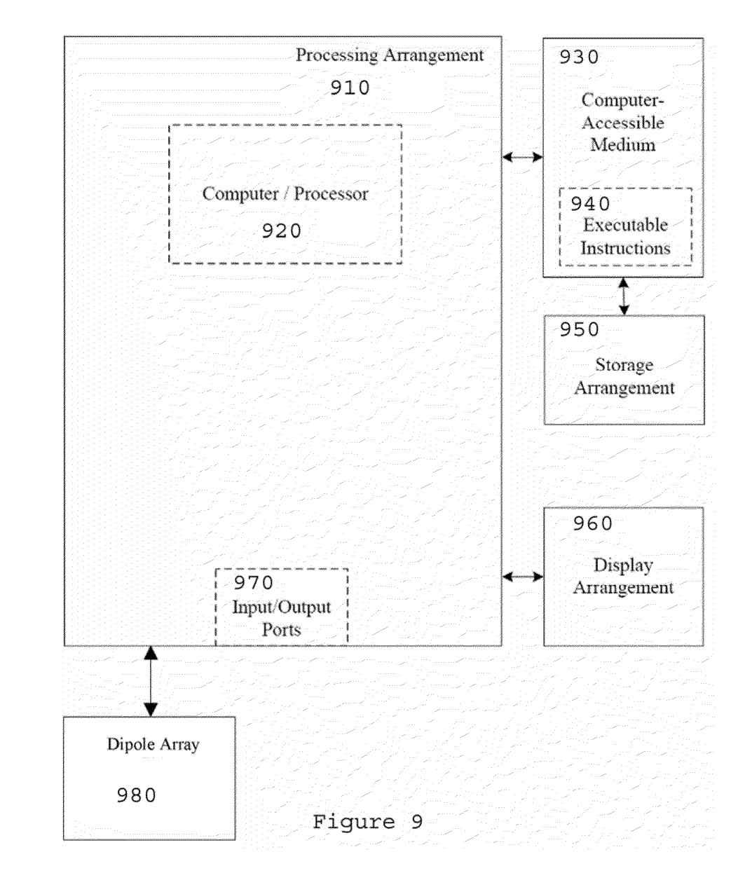

FIG. 9 shows a block diagram of an exemplary embodiment of a system according to the present disclosure. For example, exemplary procedures in accordance with the present disclosure described herein can be performed by a processing arrangement and/or a computing arrangement 910 and a coil array arrangement 980. Such processing/computing arrangement 910 can be, for example, entirely or a part of, or include, but not limited to, a computer/processor 920 that can include, for example, one or more microprocessors, and use instructions stored on a computer-accessible medium (e.g., RAM, ROM, hard drive, or other storage device).

As shown in FIG. 9, for example, a computer-accessible medium 930 (e.g., as described herein above, a storage device such as a hard disk, floppy disk, memory stick, CD-ROM, RAM, ROM, etc., or a collection thereof) can be provided (e.g., in communication with the processing arrangement 910). The computer-accessible medium 930 can contain executable instructions 940 thereon. In addition or alternatively, a storage arrangement 950 can be provided separately from the computer-accessible medium 930, which can provide the instructions to the processing arrangement 910 so as to configure the processing arrangement to execute certain exemplary procedures, processes and methods, as described herein above, for example.

Further, the exemplary processing arrangement 910 can be provided with or include an input/output arrangement 970, which can include, for example, a wired network, a wireless network, the internet, an intranet, a data collection probe, a sensor, etc. As shown in FIG. 9, the exemplary processing arrangement 910 can be in communication with an exemplary display arrangement 960, which, according to certain exemplary embodiments of the present disclosure, can be a touch-screen configured for inputting information to the processing arrangement in addition to outputting information from the processing arrangement, for example. Further, the exemplary display 960 and/or a storage arrangement 950 can be used to display and/or store data in a user-accessible format and/or user-readable format.

The foregoing merely illustrates the principles of the disclosure. Various modifications and alterations to the described embodiments will be apparent to those skilled in the art in view of the teachings herein, and especially in the appended numbered paragraphs. It will thus be appreciated that those skilled in the art will be able to devise numerous systems, arrangements, and methods, which, although not explicitly shown or described herein, embody the principles of the disclosure and can thus be within the spirit and scope of the disclosure. In addition, all publications and references referred to above are incorporated herein by reference in their entireties. It should be understood that the exemplary procedures described herein can be stored on any computer accessible medium, including a hard drive, RAM, ROM, removable disks, CD-ROM, memory sticks, etc., and executed by a processing arrangement which can be a microprocessor, mini, macro, mainframe, etc. In addition, to the extent that the prior art knowledge has not been explicitly incorporated by reference herein above, it is explicitly being incorporated herein in its entirety. All publications referenced above are incorporated herein by reference in their entireties.

### EXEMPLARY REFERENCES

The following references are hereby incorporated by reference in their entirety.
1. Reddy R, Insko E K, Noyszewski E A, Dandora R, Kneeland J B, Leigh J S. Sodium MRI of human articular cartilage in vivo. Magn Reson Med 1998; 39(5):697-701.
2. Shapiro E M, Borthakur A, Gougoutas A, Reddy R. 23Na MRI accurately measures fixed charge density in articular cartilage. Magn Reson Med 2002; 47(2):284-291.
3. Wang L, Wu Y, Chang G, Oesingmann N, Schweitzer M E, Jerschow A, Regatte R R. Rapid isotropic 3D-sodium MRI of the knee joint in vivo at 7T. J Magn Reson Imaging 2009; 30(3):606-614.
4. Madelin G, Lee J S, Inati S, Jerschow A, Regatte R R. Sodium inversion recovery MRI of the knee joint in vivo at 7T. J Magn Reson 2010; 207(1):42-52.
5. Lesperance L M, Gray M L, Burstein D. Determination of fixed charge density in cartilage using nuclear magnetic resonance. J Orthop Res 1992; 10(1):1-13.
6. Borthakur A, Shapiro E M, Beers J, Kudchodkar S, Kneeland J B, Reddy R. Sensitivity of MRI to proteoglycan depletion in cartilage: comparison of sodium and proton MRI. Osteoarthritis Cartilage 2000; 8(4):288-293.
7. Borthakur A, Mellon E, Niyogi S, Witschey W, Kneeland J B, Reddy R. Sodium and T1rho MRI for molecular and diagnostic imaging of articular cartilage. NMR Biomed 2006; 19(7):781-821.
8. Trattnig S, Friedrich K, Bogner W, Welsch G. Advanced musculoskeletal MRI at ultra-high field (7T). Imaging in Medicine 2010; 2:99-114.
18. Fitzsimmons J R, Beck B L, Brooker H R. Double resonant quadrature birdcage. Magn Reson Med 1993; 30(1):107-114.
19. Webb A G, Smith N B, Aussenhofer S, Kan H E. Use of Tailored Higher Modes of a Birdcage to Design a Simple Double-Tuned Proton/Phosphorus Coil for Human Calf Muscle Studies at 7 T. Concepts in Magn Reson Part B 2011; 39B(2):89-97.
20. Wiggins G C, Brown R, Fleysher L, Zhang B, Stoeckel B, Inglese M, Sodickson D K. A Nested Dual Frequency Birdcage/Stripline Coil for Sodium/Proton Brain Imaging at 7T. ISMRM. Stockholm, Sweden; 2010. p 1500.
21. Roemer P B, Edelstein W A, Hayes C E, Souza S P, Mueller O M. The NMR phased array. Magn Reson Med 1990; 16(2):192-225.
22. Wiggins G C, Polimeni J R, Potthast A, Schmitt M, Alagappan V, Wald L L. 96-Channel receive-only head coil for 3 Tesla: design optimization and evaluation. Magn Reson Med 2009; 62(3):754-762.
23. Hayes C E, Axel L. Noise performance of surface coils for magnetic resonance imaging at 1.5 T. Med Phys 1985; 12(5):604-607.
24. Schnell W, Renz W, Vester M, Ermert H. Ultimate Signal-to-Noise-Ratio of Surface and Body Antennas for Magnetic Resonance Imaging. IEEE T Antennas and Propagation 2000; 48(3):418-428.
25. Gabriel S, Lau R W, Gabriel C. The dielectric properties of biological tissues: II. Parametric models for the dielectric spectrum of tissues. Phys Med Biol 1996; 41(11):2271-2293.
26. Kellman P, McVeigh E R. Image reconstruction in SNR units: a general method for SNR measurement. Magn Reson Med 2005; 54(6):1439-1447.
27. Breton E, McGorty K, Wiggins G C, Axel L, Kim D. Image-guided radio-frequency gain calibration for high-field MRI. NMR Biomed 2010; 23(4):368-374.
28. Reeder S B, Wen Z, Yu H, Pineda A R, Gold G E, Markl M, Pelc N J. Multicoil Dixon chemical species separation with an iterative least-squares estimation method. Magn Reson Med 2004; 51(1):35-45.

What is claimed is:

1. A multi-frequency coil array arrangement, comprising:
a plurality of radio frequency (RF) coil arrangements having at least one first coil arrangement resonant at a single first frequency and at least one second coil arrangement resonant at a single second frequency which is lower than the first frequency.

2. The coil array arrangement of claim 1, wherein each of the RF coils includes at least one receive element which is located at or near a target object.

3. The coil array arrangement of claim 2, wherein the at least one receive element for the at least one first RF coil arrangement is located at substantially a same distance from the target object as the at least one receive element for the at least one second RF coil arrangement, and wherein the at least one receive element for the at least one first RF coil arrangement is located at least one of within or interspersed with the at least one receive element for the at least one second RF coil arrangement so as to substantially avoid shielding by the at least one receive element of the at least one second RF coil arrangement.

4. The coil array arrangement of claim 3, further comprising:
at least one excitation structure resonant only at the second frequency configured to receive a signal generated by the RF coil arrangements.

5. The coil array arrangement of claim 4, wherein the at least one excitation structure is an encircling volume coil structure.

6. The coil array arrangement of claim 5, wherein the encircling volume coil structure is at least one of (i) a birdcage (i) a Transverse Electro-Magnetic array (TEM) or (iii) an array of excitation coils.

7. The coil array arrangement of claim 4, wherein the at least one excitation structure is a high pass birdcage configured to avoid an interaction of higher modes of the high pass birdcage associated with the at least one receive element for the at least one first RF coil arrangement.

8. The coil array arrangement of claim 4, further comprising:
a computing arrangement configured to:
receive a signal from the excitation structure based on the second frequency; and
generate a uniform reference image based on the signal.

9. The coil array arrangement of claim 3, wherein the at least one receive element for the t least one second RF coil arrangement is a transmit-receive element, which is configured to function, at least in part, as a lower frequency transmit structure.

10. The coil array arrangement of claim 1, further comprising at least one third coil arrangement resonant at a third frequency which is different than the first and second frequencies.

11. The coil array arrangement of claim 2, wherein the first frequency and the second frequency are based on at least one magnetic resonance signal of at least two nuclei of the target object.

12. The coil array arrangement of claim 11, wherein one of the at least two nuclei is a low-frequency nucleus comprising at least one of helium-3, lithium-7, carbon-13, fluorine-19, oxygen-17, sodium-23, phosphorus-31 or xenon-129.

13. A dual frequency coil array arrangement, comprising:
a plurality of coil arrangements, each coil arrangement having a coil element that is resonant at a non-dual tuned frequency.

14. The coil array arrangement of claim 13, wherein the coil elements include receive elements, and the receive elements that have a lower frequency are located substantially near an 0.15 object to be imaged.

15. The coil array arrangement of claim 14, wherein the receive elements having higher frequencies are located at substantially a same distance from the object as the receive elements having lower frequency, and wherein the receive elements for the higher frequency coil arrangements are placed at least one of within or interspersed with the receive elements for the lower frequency coil arrangements to avoid shielding by the receive elements of the lower frequency receive arrangements.

16. The coil array arrangement of claim 15, wherein excitation for the lower frequency coil arrangements is provided by an excitation arrangement resonant only at lower frequencies.

17. The coil array arrangement of claim 16, wherein the excitation arrangement is an encircling volume coil structure.

18. The coil array arrangement of claim 17, wherein the encircling volume coil structure is at least one of (i) a birdcage (i) a TEM or (iii) an array of excitation coils.

19. The coil array of claim 16, wherein the excitation arrangement is a high pass birdcage configured to avoid interaction of higher modes of the high pass birdcage with the higher frequency coil arrangements.

20. The coil array arrangement of claim 16, wherein the lower frequency coil arrangements are configured to generate a signal while the receive elements of lower frequency coil arrangements are detuned in order to generate a uniform reference image.
